(19) United States
(12) Patent Application Publication
(10) Pub. No.: US 2014/0117428 A1
(43) Pub. Date: May 1, 2014

(54) Image Sensor

(71) Applicants: Ju Il LEE, Seongnam-si (KR); Man Lyun HA, Icheon-si (KR)

(72) Inventors: Ju Il LEE, Seongnam-si (KR); Man Lyun HA, Icheon-si (KR)

(21) Appl. No.: 13/765,203

(22) Filed: Feb. 12, 2013

(30) Foreign Application Priority Data
Oct. 31, 2012 (KR) 10-2012-0121945

(51) Int. Cl. H01L 27/146

(52) U.S. Cl. CPC H01L 27/14643
USPC 257/292

(57) ABSTRACT

Disclosed is an image sensor including a photodiode region on a first conductive type semiconductor substrate; a first floating diffusion region having a second conductive type, separate from the photodiode region; a second floating diffusion region having the second conductive type, separate from the first floating diffusion region; a first gate on the semiconductor substrate between the photodiode region and the first floating diffusion region; and a second gate on the semiconductor substrate between the first floating diffusion region and the second floating diffusion region, wherein the semiconductor substrate and the first floating diffusion region forms a junction area that is larger than that of the semiconductor substrate and the second floating diffusion region.

This application claims the benefit of Korean Patent Application No. 10-2012-0121945, filed on Oct. 31, 2012, which is incorporated herein by reference as if fully set forth herein.

### BACKGROUND OF THE INVENTION

1. Field of the Invention

The present invention relates to an image sensor and more particularly a wide dynamic range (WDR) image sensor.

2. Discussion of the Related Art

An image sensor is a semiconductor device which converts an optical image into an electric signal. Representative image sensors include charged coupled device (CCD) image sensors and complementary metal oxide semiconductor (CMOS) image sensors.

In general, a CMOS image sensor is classified into 3T, 4T and 5T-types depending on the number of transistors constituting a unit pixel. The unit pixel includes one photodiode and at least one transistor (for example, a transfer transistor, a reset transistor, a select transistor and/or a drive transistor).

The image sensor is not capable of treating or processing all information of an actual scene since the obtainable dynamic region is considerably smaller than the dynamic region of the actual image. In particular, when an image is obtained under an environment such as backlight, the image sensor cannot sufficiently obtain information of both the brightest region and the darkest region of the image, and image qualities of the corresponding region(s) may be disadvantageously seriously deteriorated.

In order to solve this disadvantage, an image sensor utilizes a wide dynamic range (WDR) method. The WDR method improves image qualities using two or more images and widens a dynamic region, based on images obtained for different exposure times to improve image quality.

### SUMMARY OF THE INVENTION

Accordingly, the present invention is directed to an image sensor that substantially obviates one or more problems due to limitations and disadvantages of the related art.

It is one object of the present invention to provide an image sensor that accomplishes wide dynamic range (WDR) and reduces generation of dark current at a low luminance.

To achieve these objects and other advantages, and in accordance with the purpose(s) of the invention as embodied and broadly described herein, an image sensor may include a photodiode region on a semiconductor substrate having a first conductive type; a first floating diffusion region having a second conductive type, separate from the photodiode region; a second floating diffusion region having the second conductive type, separate from the first floating diffusion region; a first gate on the semiconductor substrate between the photodiode region and the first floating diffusion region; and a second gate on the semiconductor substrate between the first floating diffusion region and the second floating diffusion region, wherein the semiconductor substrate and the first floating diffusion region forms a junction area that is larger than that of (e.g., formed by) the semiconductor substrate and the second floating diffusion region.

The photodiode region may include a first impurity region having the second conductive type and a second impurity region having the second conductive type, from the bottom to the top in this order (e.g., thereon).

A junction area of the semiconductor substrate and the first impurity region may be larger than that of the semiconductor substrate and the second floating diffusion region.

The image sensor may further include a third impurity region having the first conductive type, between an upper or uppermost surface of the semiconductor substrate and an upper or uppermost surface of the first floating diffusion region.

The image sensor may further include a buried channel region having the second conductive type, in the semiconductor substrate under the second gate; and an impurity region having the first conductive type, in the semiconductor substrate between the buried channel region and the second gate.

The image sensor may further include a light-shielding portion on or over the first gate and the second gate, such that the light-shielding portion is in or over the first floating diffusion region, and blocks permeation or diffusion of light into the first floating diffusion region. The light-shielding portion may be electrically connected to the first gate and/or the second gate.

The image sensor may further include first to third diffusion regions having the second conductive type, separate from the second floating diffusion region; a third gate on the semiconductor substrate between the second floating diffusion region and the first diffusion region; a fourth gate on the semiconductor substrate between the first diffusion region and the second diffusion region; and a fifth gate on the semiconductor substrate between the second diffusion region and the third diffusion region.

A first control signal may be applied to the first gate, a second control signal may be applied to the second gate, a third control signal may be applied to the third gate, a power supply voltage may be applied to the first diffusion region, a fourth control signal may be applied to the fifth gate, and/or the third diffusion region may be or may be connected to an output terminal (e.g., of the unit pixel).

In accordance with another aspect of the present invention, an image sensor may include a photodiode region on a semiconductor substrate having a first conductive type; a first floating diffusion region having a second conductive type, separate from the photodiode region; a second floating diffusion region having the second conductive type, separate from the first floating diffusion region; a first gate on the semiconductor substrate between the photodiode region and the first floating diffusion region; and a junction field-effect transistor in the semiconductor substrate between the first floating diffusion region and the second floating diffusion region.

The junction field-effect transistor may include a fourth impurity region having the second conductive type, and a fifth impurity region having the first conductive type, from the bottom to the top in this order.

The image sensor may further include first to third diffusion regions having the second conductive type, separate from the second floating diffusion region; a second gate on the semiconductor substrate between the second floating diffusion region and the first diffusion region; a third gate on the semiconductor substrate between the first floating diffusion region and the second diffusion region; and a fourth gate on the semiconductor substrate between the second diffusion region and the third diffusion region, wherein a first control signal is applied to the first gate, a second control signal is applied to the fifth impurity region, a third control signal is applied to the second gate, a power supply voltage is applied to the first diffusion region, a fourth control signal is applied to the fourth gate, and the third diffusion region may be or may be connected to an output terminal (e.g., of the unit pixel).

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and along with the description serve to explain the principle(s) of the invention. In the drawings:

FIG. 1 shows a layout of a unit pixel of an image sensor according to one embodiment;

FIG. 2 is a cross-sectional view taken along the direction AB of the image sensor shown in FIG. 1;

FIG. 3 is a cross-sectional view of a unit pixel of an image sensor according to another embodiment; and

FIG. 4 is a cross-sectional view of a unit pixel of an image sensor according to another embodiment.

### DETAILED DESCRIPTION OF THE INVENTION

The above and other objects, features and other advantages of the present invention will be more clearly understood from the following detailed description taken in conjunction with the accompanying drawings. Prior to the description of the embodiments, with regard to descriptions of certain embodiments according to the present invention, it will be understood that, when one element such as a layer or film, a region or a structure is referred to as being formed “on” or “under” another element such as a substrate, a layer or film, a region, a pad or a pattern, the one element may be directly formed “on” or “under” the another element, or be indirectly formed “on” or “under” the another element via one or more intervening elements therebetween. Further, “on” or “under” each element is described based on the drawings.

In the drawings, the thicknesses or sizes of respective layers are exaggerated, omitted or schematically illustrated for convenience and clarity of description. Therefore, the sizes of respective elements as shown in the drawings do not wholly reflect the actual sizes thereof. Hereinafter, an image sensor according to one or more embodiments of the present invention will be described in detail.

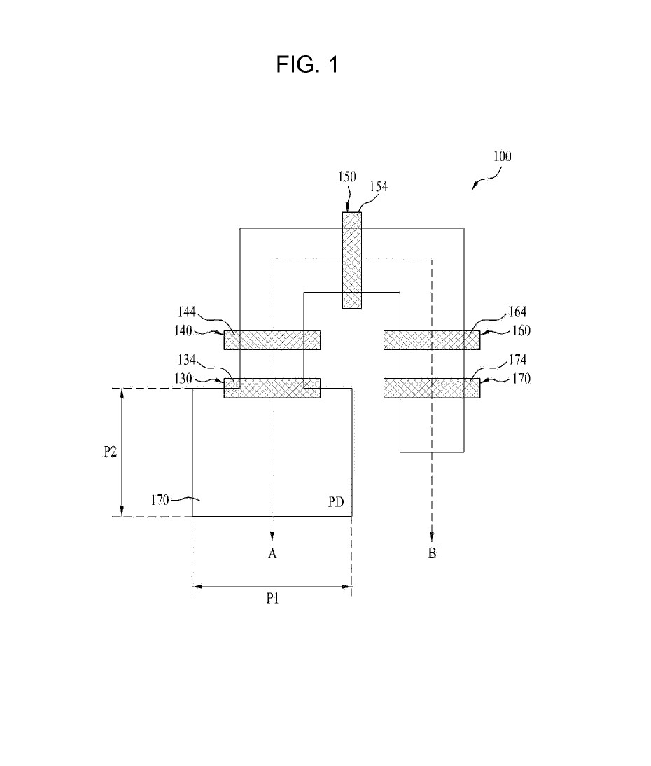

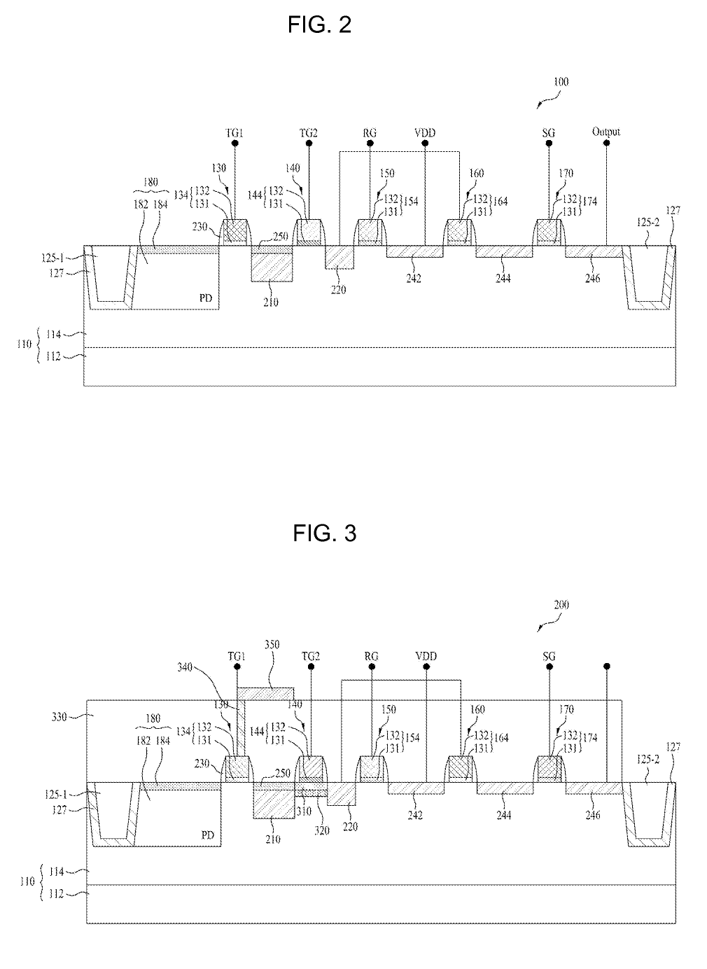

FIG. 1 shows a layout of a unit pixel of an image sensor 100 according to an embodiment. FIG. 2 is a cross-sectional view taken along the direction AB of the image sensor shown in FIG. 1.

Referring to FIGS. 1 and 2, the image sensor 100 includes one photodiode region 180 and five transistors 130, 140, 150, 160 and 170 in one unit pixel. For example, the first transistor 130 is a first transfer transistor, the second transistor 140 is a second transfer transistor, the third transistor 150 is a reset transistor, the fourth transistor 160 is a drive transistor, and the fifth transistor 170 is a select transistor.

The image sensor 100 includes a semiconductor substrate 110, device isolation films 125-1 and 125-2, a photodiode region 180 including a first impurity region 182 having a second conductive type and a second impurity region 184 having a first conductive type, a third impurity region 127 having the first conductive type, first to fifth gates 134, 144, 154, 164 and 174, a first floating diffusion region 210, a second floating diffusion region 220, first to third diffusion regions 242, 244 and 246 having the second conductive type, and a fourth impurity region 250 having the first conductive type.

The semiconductor substrate 110 includes a silicon substrate 112 which may include a polycrystalline semiconductor (for example, silicon) comprising a high concentration of a first conductive type (P++) impurity and a low-concentration first conductive type (P−) epilayer 114, formed on the semiconductor substrate 110 by an epitaxial process. For example, the concentration of p-type impurities implanted in the epilayer 114 may be lower than that of the p-type impurities implanted in the silicon substrate 112.

The photodiode region 180 has a wide depletion region and a large depth through the low-concentration first conductive type epilayer 114. For this reason, collection of photocharges at low voltage and the photosensitivity can be improved.

The device isolation films 125-1 and 125-2 are formed in the semiconductor substrate 110 to define an active region and an isolation region. For example, the device isolation films 125-1 and 125-2 may be formed in the epilayer 114 using a shallow trench isolation (STI) or local oxidation of silicon (LOCOS) process.

The first to fifth gates 134, 144, 154, 164 and 174 may be spaced apart or separate from one another on the semiconductor substrate 110. For example, the first gate 134 may be a first transfer gate, the second gate 144 may be a second transfer gate, the third gate 154 may be a reset gate, the fourth gate 164 may be a drive gate and the fifth gate 174 may be a select gate.

A spacer 230 may be formed on sidewalls of each of the first to fifth gates 134, 144, 154, 164 and 174.

Each of the first to fifth gates 134, 144, 154, 164 and 174 may include an insulating film 131 and a gate electrode 132. The insulating film 131 and the gate electrode 132 may be formed in this order on the semiconductor substrate 110. The insulating film 131 may comprise or consist essentially of an oxide film and/or a nitride film (e.g., Silicon dioxide, silicon nitride, hafnium oxide, etc.), and may have a mono- or multi-layer structure. The gate electrode 132 may comprise or consist essentially of polysilicon.

The photodiode region 180 may be formed in a light receiving region (P1×P2) of the semiconductor substrate 110 between the device isolation film 125-1 and the first gate 134, and may electrically contact the first gate 134. The light receiving region (P1×P2) may be an active region of the semiconductor substrate 110 and form the photodiode region 180 in order to sense light.

The photodiode region 180 may be in a light receiving region of the semiconductor substrate 110 (P1×P2) doped with an impurity. The photodiode region 180 may include a first impurity region 182 having the second conductive type and a second impurity region 184 having the first conductive type, disposed in this order from the bottom to the top in the light receiving region (P1×P2) of the semiconductor substrate 110.

The first impurity region 182 may be a region doped with a second conductive type impurity (for example, an n-type impurity) in the light receiving region (P1×P2) of the semiconductor substrate 110. The first impurity region 182 may form a PN-junction with the semiconductor substrate 110.

The second impurity region 184 may be formed on the surface of the semiconductor substrate 110 between the device isolation films 125-1 and 125-2 and the first source region 190. The second impurity region 184 may be in an upper part of the second conductive doping region 170. A lower or lowermost surface of the second impurity region 184 may contact an upper surface of the first impurity region 182, and one side of the second impurity region 184 may electrically contact the first gate 134.

For example, the second impurity region 184 may be formed in a same region of an epilayer 112 as the first impurity region 182, on or above the semiconductor substrate 110. The second impurity region 184 may isolate the upper surface of the first impurity region 182 from the surface of the semiconductor substrate 110.

The second impurity region 184 may be doped with a high concentration of first conductive type (for example, p+ type) impurities. The second impurity region 184 may also prevent dangling bonds in the photodiode region 180 and inhibit movement of dark current along the surface of the photodiode region 180. In another embodiment, the second impurity region 184 which functions to inhibit the dark current may be omitted, and in this case, the photodiode region 180 may comprise or consist of the first impurity region 182, which may extend to the surface (e.g., uppermost surface) of the epilayer 114.

The p-type epilayer 114 and the photodiode region 180 may be stacked or formed in this order in the semiconductor substrate 110 at one side of the first gate 134, and a PNP junction structure including the first conductive type (for example, p-type) epilayer 114, the second conductive type (for example, n-type) first impurity region 182 and the first conductive type second impurity region 184 may be formed in sequence.

The third impurity region 127 may be formed in the active region of the semiconductor substrate 110, for example, the epilayer 114, adjacent to the surface of the device isolation films 125-1 and 125-2. The third impurity region 127 may contact the device isolation films 125-1 and 125-2, and surround the device isolation films 125-1 and 125-2.

A part of the third impurity region 127 may be between the device isolation film 125-1 or 125-2 and the photodiode region 180, and may isolate the first impurity region 182 from the device isolation film 125-1 or 125-2. The third impurity region 127 blocks movement of leakage current from the first impurity region 182 through the isolation films 125-1 and 125-2, and thereby prevents crosstalk between adjacent unit pixels.

The first floating diffusion region 210 may be formed in the semiconductor substrate 110 between the first gate 134 and the second gate 144. The second floating diffusion region 220 may be formed in the semiconductor substrate 110 between the second gate 144 and the third gate 154. The first floating diffusion region 210 and the second floating diffusion region 220 may be regions doped with second conductive type impurity ions in the epilayer 114. The first floating diffusion region 210 and the second floating diffusion region 220 may be formed through the same or different processes (e.g., simultaneous or sequential ion implantation).

The fourth impurity region 250 may be formed in the first floating diffusion region 210. The fourth impurity region 250 may be between an upper or uppermost surface of the epilayer 114 and an upper surface of the first floating diffusion region 210, and like the second impurity region 184, the fourth impurity region 250 can inhibit dark current which flows along the upper surface of the first floating diffusion region 210.

The concentration of the second conductive type impurities in the first floating diffusion region 210 may be different from the concentration of second conductive type impurities in the second floating diffusion region 220. For example, the concentration of impurities in the second floating diffusion region 220 may be higher than the concentration of impurities in the first floating diffusion region 210, but the invention is not limited thereto.

The first diffusion region 242 may be formed in the semiconductor substrate 110 between the third gate 154 and the fourth gate 164. The second diffusion region 244 may be formed in the semiconductor substrate 110 between the fourth gate 164 and the fifth gate 174. The third diffusion region 246 may be formed between the fifth gate 246 and the device isolation film 125-2. Each of the first to third diffusion regions 242, 244 and 246 may serve as a source and/or a drain of a transistor in the unit pixel (e.g., the drive transistor 160 and/or the select transistor 170).

A volume of the first floating diffusion region 210 may be smaller than that of the photodiode region 180 (for example, first impurity region 182), and a volume of the second floating diffusion region 220 may be smaller than that of the first floating diffusion region 210.

A junction area of the first floating diffusion region 210 may be smaller than that of the photodiode region 180 (for example, first impurity region 182), and a junction area of the second floating diffusion region 220 may be smaller than that of the first floating diffusion region 210. The junction area may be a p-n junction area between the floating diffusion region and the semiconductor substrate 110.

Junction areas of the first floating diffusion region 210 and the second floating diffusion region 220 may be proportional to capacitance. That is, a size or capacitance of the PN junction area may decrease or increase from the first impurity region 182, the first floating diffusion region 210 and the second floating diffusion region 220 in this order.

A first control signal TG1 may be applied to the first gate 134, and the first transistor 130 may be turned on or off through the first control signal TG1.

A second control signal TG2 may be applied to the second gate 144, and the second transistor 140 may be turned on or off through the second control signal TG2.

A third control signal RG may be applied to the third gate 154, and the third transistor 150 may be turned on or off through the third control signal RG.

A fourth control signal SG may be applied to the fifth gate 174, and the fifth transistor 170 may be turned on or off through the fourth control signal RG.

The second floating diffusion region 220 may be electrically connected to the fourth gate 164, and the fourth transistor 160 may be turned on or off or controlled by the variation in voltage of the second floating diffusion region 220.

A power supply voltage (VDD) may be applied to the first diffusion region 242. An output terminal may be connected to the third diffusion region 246, and the output of one or more unit pixels may be obtained through the output terminal.

In the present embodiment, the following operation may be made under a first luminance environment (condition). The first luminance environment may be a low luminance, and the criteria for setting or defining the first luminance environment may be determined by a user.

The first control signal TG1 turns on the first transistor 130, and the second control signal TG2 turns off the second transistor 140, thus causing transfer of the charge (e.g., a signal) generated by light from the photodiode region 180 to the first floating diffusion region 210.

After the charge is transferred to the first floating diffusion region 210, the first control signal TG1 turns off the first transistor 130, and the charge is stored in the first floating diffusion region 210 for the time for global shutter function. Here, the time for global shutter function may also be determined by the user.

After the time for global shutter function passes, the second control signal TG2 turns on the second transistor 140 to transfer the signal or charge from the first floating diffusion region 210 to the second floating diffusion region 220. Reading the signal or charge transferred to the second floating diffusion region 220 using the output terminal may be the same as a reading operation of a general image sensor.

For example, the first and second control signals TG1 and TG2 turn off the first transistor 130 and the second transistor 140, and the fourth control signal SG turns on the fifth transistor 170 to read the voltage on the output terminal.

The capacitance increases from the first impurity region 182, the first floating diffusion region 210, to the second floating diffusion region 220 in this order. For this reason, high sensitivity can be obtained at a low luminance.

In the present embodiment(s), generation of dark current can be reduced, since the first floating diffusion region 210 has a smaller junction area than the first impurity region 182. Also, the first floating diffusion region 210 has superior charge (e.g., electron) storage functionality, and can thus maintain charge storage for a long time, thus being advantageous in the global shutter operation, since it has a larger junction area than the second floating diffusion region 220.

In the present embodiment(s), the following operation may be performed in a second luminance environment. The second luminance environment may have a higher luminance than the first luminance environment. The criteria for setting or defining the second luminance environment may be determined by the user.

The first transistor 130 and the second transistor 140 are simultaneously turned on to transfer a signal OR charge generated by light from the photodiode region 180 to the first floating diffusion region 210 and the second floating diffusion region 220. The transferred signal OR charge is stored in the first floating diffusion region 210 and the second floating diffusion region 220 for the time for global shutter function. Here, the time for global shutter function may be determined by the user. After the time for global shutter function passes, the signal or charge which is stored in the first floating diffusion region 210 and the second floating diffusion region 220 is read.

The total capacitance of the first floating diffusion region 210 and the second floating diffusion region 220 may represent a suitable sensitivity at high luminance. Also, there is no problem associated with dark current, since the signal or charge is strong (or high) at a high luminance.

As described above, the image sensor of the present embodiment(s) includes two transistor gates 134 and 144 and two floating diffusion regions 210 and 220, realizes 2-slope sensitivity at a low luminance and a high luminance, and thereby realizes wide dynamic range (WDR). The present image sensor also reduces generation of dark current in a low luminance environment.

The first conductive type may be p-type, and the p-type impurity may be boron (B), indium (In), or gallium (Ga). The second conductive type may be n-type, and the n-type impurity may be arsenic (As), phosphorus (P), or antimony (Sb). In another embodiment, the first conductive type may be n-type, and the second conductive type may be p-type.

FIG. 3 is a cross-sectional view of a unit pixel of an image sensor 200 according to another embodiment. The same reference numerals in FIGS. 2 and 3 represent the same configurations and/or structures, and the contents described above for such configurations and/or structures may be omitted or described in brief.

Referring to FIG. 3, in comparison with the embodiment 100 shown in FIG. 2, the image sensor 200 may further include a fifth impurity region 310 having the first conductive type, a buried channel region 320 having the second conductive type, an insulating and/or dielectric layer 330, a contact 340, and a light-shielding portion 350.

The buried channel region 320 may be spaced apart or separate from the second gate 144, in the epilayer 114 under the second gate 144. For example, the buried channel region 320 may be under the second gate and formed in the epilayer 114 between the first floating diffusion region 210 and the second floating diffusion region 220. One end of the buried channel region 320 may contact the first floating diffusion region 210 and the other end of the buried channel region 320 may contact the second floating diffusion region 220.

The buried channel region 320 and the first floating diffusion region 210 may be formed using the same or different processes (e.g., the same or separate ion implantation process[es]).

The fifth impurity region 310 may be formed in the epilayer 114 in or on the buried channel region 320, and the second gate 144 may be formed thereover. The fifth impurity region 310 may contact the fourth impurity region 250, and may be simultaneously formed through using same process as the first conductive type fourth impurity region 250, but the present invention is not limited thereto. That is, the fourth impurity region 250 and the fifth impurity region 310 may be independently formed through separate processes.

The fifth impurity region 310 may contact a lower surface of the gate oxide layer 131, the first floating diffusion region 210 and the second floating diffusion region 220. The buried channel region 320 may be a channel region of the second transistor 140, and may be isolated from the surface of the epilayer 114 by the fifth impurity region 310.

Accordingly, the embodiment includes the fifth impurity region 310 and the buried channel region 320, thus reducing generation of dark current when a signal or charge is transferred from the first floating diffusion region 210 to the second floating diffusion region 220.

The insulating and/or dielectric layer 330 may be formed on the semiconductor substrate and the first to fifth gates 134, 144, 154, 164 and 174. The insulating and/or dielectric layer 330 may be a pre-metal dielectric (PMD), may comprise or be formed of borophosphosilicate glass (BPSG), phosphosilicate glass (PSG), or undoped silicate glass (USG), and may have a mono- or multi-layer structure and further include an optional lowermost silicon nitride layer.

The light-shielding portion 350 may be formed on the insulating and/or dielectric layer 330 such that it corresponds to or is over the first floating diffusion region 210. The light-shielding portion 350 functions to block permeation or diffusion of light into the first floating diffusion region 210. The light-shielding portion 350 may comprise or be formed of a light-shielding material, for example, a metal such as Cu, Al, W, Ti or Ni, and may have a mono- or multi-layer structure.

The contact 340 may connect the first gate 134 to the light-shielding portion 350 through the insulating and/or dielectric layer 330. In this case, the light-shielding portion 340 may serve as a metal line layer or interconnect to the first gate 134. In another embodiment, the image sensor may further include a contact (not shown) that connects the light-shielding portion 350 to the second gate 144 through the insulating and/or dielectric layer 330. In this case, the light-shielding portion 340 may serve as a metal line layer or interconnect to the second gate 144.

As described above, under the first luminance environment, the signal or charge is stored in the first floating diffusion region 210 for the global shutter function time. The first floating diffusion region 210 may also serve as a photodiode, comprising a p-n junction with the epilayer 114. When the light-shielding portion 340 is not formed or present, unnecessary charges may be generated in the first floating diffusion region 210 by light incident upon the first floating diffusion region 210, and a noise signal may thus be generated. Accordingly, the present embodiment includes the light-shielding portion 350, thereby inhibiting generation of undesirable noise under a low luminance environment.

Also, the present embodiment may use the first floating diffusion region 210 where light is shielded by the light-shielding portion 350 as a reference pixel, serving as a reference for calibration of dark current, thus reducing the chip size.

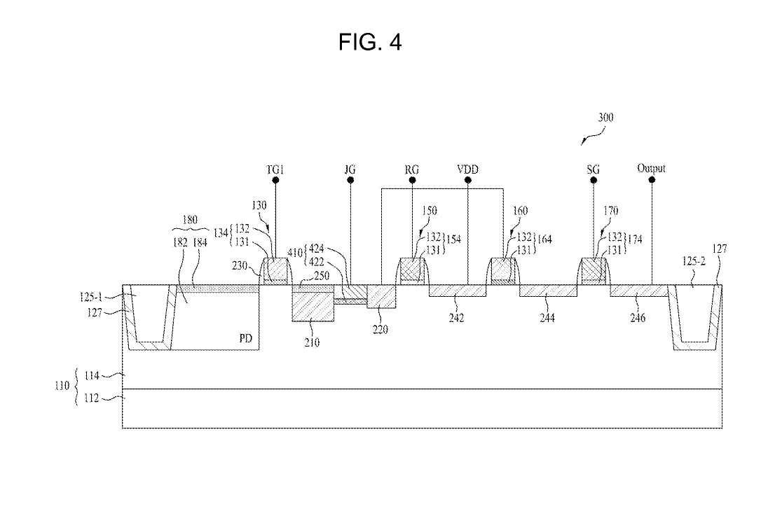

FIG. 4 shows is a cross-sectional view of a unit pixel of an image sensor 300 according to another embodiment. The same reference numerals in FIGS. 2-4 represent the same configurations and/or structures, and the contents described above with regard to such configurations and/or structures may be omitted or described in brief.

Referring to FIG. 4, the image sensor 300 may include a junction field-effect transistor 410, instead of the second gate 144 of the second transistor 140 as in the embodiment shown in FIG. 2.

The junction field-effect transistor 410 may be formed in the epilayer 114 between the first floating diffusion region 210 and the second floating diffusion region 220. The junction field-effect transistor 410 may include a seventh impurity region 422 having the second conductive type, and an eighth impurity region 424 having the first conductive type, from the bottom to the top in this order.

For example, the eighth impurity region 424 may be a p+ junction gate, and the seventh impurity region 422 may be a channel region.

A fifth control signal JG may be applied to the eighth impurity region 424, and the junction field-effect transistor 410 may be turned on or off using the fifth control signal JG. For example, when a voltage of the control signal JG is −3.3V, the junction field-effect transistor 410 turns on, and the first floating diffusion region 210 may be thus electrically connected to the second floating diffusion region 220. On the other hand, when a voltage of the control signal JG is 0V, the junction field-effect transistor 410 turns off, and the first floating diffusion region 210 may be thus electrically isolated from the second floating diffusion region 220.

In the present embodiment, capacitances of the first floating diffusion region 210 and the second floating diffusion region 220 may be changed according to a voltage of the control signal JG or the concentration or dose of a first conductive type impurity injected or implanted into the eighth impurity region 424, and sensitivity can thus be controlled.

Also, in the present embodiment, the junction field-effect transistor 410 is used, instead of the second gate 144 shown in FIG. 2, generation of dark current can be fundamentally inhibited at the channel.

The embodiments according to the present invention provide an image sensor that realizes wide dynamic range (WDR) and reduces generation of dark current at a low luminance.

Particular features, structures, or characteristics described in connection with an embodiment are included in at least one embodiment of the present invention, and not necessarily in all embodiments. Furthermore, the particular features, structures, or characteristics of any specific embodiment of the present invention may be combined in any suitable manner with one or more other embodiments, or may be changed by those skilled in the art to which the embodiments Pertain. Therefore, it is to be understood that contents associated with such combination or change fall within the spirit and scope of the present disclosure.

What is claimed is:

1. An image sensor comprising:
a photodiode region on or in a semiconductor substrate having a first conductive type;
a first floating diffusion region having a second conductive type, separate from the photodiode region on or in the first conductive type semiconductor substrate;
a second floating diffusion region having the second conductive type, separate from the first floating diffusion region;
a first gate on or over the semiconductor substrate, between the photodiode region and the first floating diffusion region; and
a second gate on or over the semiconductor substrate, between the first floating diffusion region and the second floating diffusion region,
wherein the semiconductor substrate and the first floating diffusion region form a junction area that is larger than that of the semiconductor substrate and the second floating diffusion region.

2. The image sensor according to claim 1, wherein the photodiode region comprises a first impurity region having the second conductive type and a second impurity region thereon, having the first conductive type.

3. The image sensor according to claim 2, wherein the semiconductor substrate and the first impurity region form a junction area that is larger than that of the semiconductor substrate and the floating diffusion region.

4. The image sensor according to claim 1, further comprising a third impurity region having the first conductive type, in an upper surface of the semiconductor substrate and at an upper surface of the first floating diffusion region.

5. The image sensor according to claim 1, further comprising:
a buried channel region having the second conductive type, in the semiconductor substrate under the second gate; and
an impurity region having the first conductive type, in the semiconductor substrate between the buried channel region and the second gate.

6. The image sensor according to claim 1, further comprising a light-shielding portion on or over the first gate, the second gate, and the first floating diffusion region, configured to block permeation or diffusion of light into the first floating diffusion region.

7. The image sensor according to claim 4, further comprising a light-shielding portion on or over the first gate, the second gate, and the light-shielding portion, configured to block permeation or diffusion of light into the first floating diffusion region.

8. The image sensor according to claim 5, wherein the light-shielding portion is electrically connected to the first gate or the second gate.

9. The image sensor according to claim 1, further comprising:
first to third diffusion regions having the second conductive type, separate from the second floating diffusion region.

10. The image sensor according to claim 9, further comprising:
a third gate on the semiconductor substrate between the second floating diffusion region and the first diffusion region.

11. The image sensor according to claim 10, further comprising:
a fourth gate on the semiconductor substrate between the first diffusion region and the second diffusion region.

12. The image sensor according to claim 11, further comprising:
a fifth gate on the semiconductor substrate between the second diffusion region and the third diffusion region.

13. The image sensor according to claim 12, wherein a first control signal is applied to the first gate, a second control signal is applied to the second gate, a third control signal is applied to the third gate, a power supply voltage is applied to the second conductive type first diffusion region, a fourth control signal is applied to the fifth gate, and the third diffusion region is or is connected to an output terminal.

14. An image sensor comprising:
a photodiode region on or in a semiconductor substrate having a first conductive type;
a first floating diffusion region having a second conductive type, separate from the photodiode region on or in the semiconductor substrate;
a second floating diffusion region having the second conductive type, separate from the first floating diffusion region;
a first gate on the semiconductor substrate between the photodiode region and the first floating diffusion region; and
a junction field-effect transistor in the semiconductor substrate between the first floating diffusion region and the second floating diffusion region.

15. The image sensor according to claim 14, wherein the junction field-effect transistor comprises a fourth impurity region having the second conductive type and a fifth impurity region thereon, having the first conductive type.

16. The image sensor according to claim 15, further comprising:
first to third diffusion regions having the second conductive type, separate from the second floating diffusion region.

17. The image sensor according to claim 16, further comprising:
a second gate on the semiconductor substrate between the second floating diffusion region and the first diffusion region.

18. The image sensor according to claim 17, further comprising:
a third gate on the semiconductor substrate between the first floating diffusion region and the second diffusion region.

19. The image sensor according to claim 18, further comprising:
a fourth gate on the semiconductor substrate between the second diffusion region and the third diffusion region.

20. The image sensor according to claim 19, wherein a first control signal is applied to the first gate, a second control signal is applied to the first conductive type fifth impurity region, a third control signal is applied to the second gate, a power supply voltage is applied to the second conductive type first diffusion region, a fourth control signal is applied to the fourth gate, and the third diffusion region is or is connected to an output terminal.
